(19) United States
(12) Patent Application Publication
(10) Pub. No.: US 2004/0200572 A1
(43) Pub. Date: Oct. 14, 2004

(54) Assembling pellicle frames and photomasks

(76) Inventors: Edita Tejnil, San Carlos, CA (US); Emily Y. Shu, San Jose, CA (US)

Correspondence Address: Timothy N. Trop, TROP, PRUNER & HU, P.C., STE 100, 8554 KATY FWY, HOUSTON, TX, 77024-1841, US

(21) Appl. No.: 10/409,289

(22) Filed: Apr. 8, 2003

(51) Int. Cl. B32B 31/00; C23F 1/00; H01L 21/306

(52) U.S. Cl. 156/345.1

(57) ABSTRACT

Elements of photomasks may be secured using a liquid bonding material that may be cured in place. In one embodiment, a liquid bonding material may be cured using light exposure. Particularly with hard pellicles, the use of a liquid bonding material that is curable to a relatively rigid adhesion form may be advantageous since the pellicle may be positioned accurately before curing is implemented.

### BACKGROUND

This invention relates generally to techniques for forming semiconductor integrated circuits.

A pattern may be transferred successively to a number of silicon wafers. Thus, a pattern that may be resident on a photomask may be transferred to a number of wafers so that identical semiconductor wafer may be made through a photolithographic process.

Generally, the photolithographic process involves the use of a photomask. A pellicle assembly over the patterned area of the mask is used to protect the critical mask pattern from particles. Particles on the patterned area would print as killer defects on the wafer. Particles on the pellicle are sufficiently out of focus of the wafer exposure tool that they do not appreciably affect the printed pattern. A pellicle may be mounted on a pellicle frame. The pellicle frame is then mounted on the photomask.

In 157 nanometer lithography, the lack of proper materials for conventional polymer based pellicles has brought up the possibility of using hard pellicles, which are solid state materials transparent to 157 nm light such as fluorine doped fused silica, calcium fluoride, etc. The hard pellicles are optically thick and any distortion produces registration and focusing errors in the pattern printed with the mask. Pellicle distortion may result from stress produced when the pellicle is mounted on a photolithographic mask.

In 157 nanometer lithography, the pellicle film may be a fused silica plate of a fraction of one millimeter thick. In such case, both the stress at the boundary between the pellicle frame and the mask and between the pellicle frame and the pellicle may be important. The stress in the 157 nanometer hard pellicles produces local pellicle tilt which in turn causes pattern registration errors in the image printed with the pellicle protected mask.

Currently pellicles may be mounted in lithographic masks using adhesives. For hard pellicles, the mounting involves the use of a lot of force, could be up to many thousands of kilograms per square meter, to achieve pellicle adhesion. The impact from the mounting stress may cause bending of the hard pellicles. As a result, the quality of registration of the printed image may suffer. This approach may not be viable with 157 nanometer lithography due to the use of hard pellicles.

Thus, there is a need for better ways to mount pellicles to photomasks.

### BRIEF DESCRIPTION OF THE DRAWINGS

FIG. 1 is a perspective view of one embodiment of the present invention;

FIG. 2 is a partial cross-sectional view taken generally along the line 2-2 in FIG. 1;

FIG. 3 is a partial, cross-sectional view corresponding to FIG. 1 after the pellicle frame has been positioned on the photomask in accordance with one embodiment of the present invention;

FIG. 4 is a partial, cross-sectional view corresponding to FIG. 3 at a subsequent stage in accordance with one embodiment of the present invention;

FIG. 5 is a partial, cross-sectional view corresponding to FIG. 4 at a subsequent stage in accordance with one embodiment of the present invention;

FIG. 6 is a cross-sectional view corresponding to FIG. 4 that has been greatly enlarged in accordance with still another embodiment of the present invention; and

FIG. 7 is a schematic depiction of a pellicle mounting system in accordance with one embodiment of the present invention.

### DETAILED DESCRIPTION

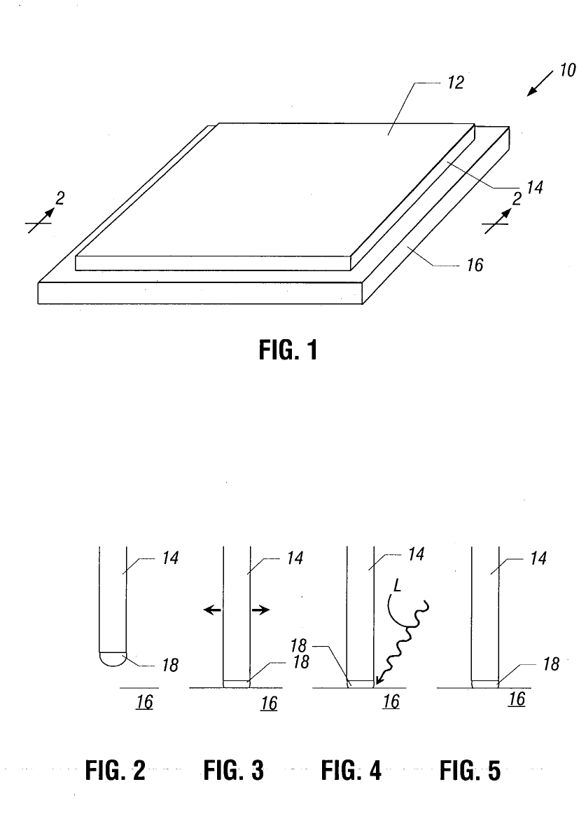

Referring to FIG. 1, a hard pellicle 12 may be mounted on a pellicle frame 14. The pellicle frame 14 may in turn be secured to a photomask 16.

Referring to FIG. 2, the pellicle frame 14 may have curable, cross-linkable adhesive 18 positioned on its lower edge. In one embodiment, the adhesive 18 may be an optically clear ultraviolet or thermally curable adhesive. The adhesive 18 advantageously is a liquid at room temperature and has relatively low viscosity, for examples under 500 centipoise, before curing and cures to a mechanically strong, stable bonding material.

The liquid adhesive 18 may be applied along the edge of the pellicle frame 14 to form a continuous bead of liquid free of bubbles. The adhesive 18 may be precured by heating the parts or by a short ultraviolet exposure, for example 10 seconds of exposure, to a 100 watt mercury lamp at six inches. After the precure, the parts may be aligned and positioned without using fixtures in some cases. The precure may then be followed by a final cure for 5 to 10 minutes in one embodiment.

In one embodiment, an optical adhesive may be an adhesive available from Norland Products, Inc., Cranbury, N.J. 08512, including NOA61, NOA63, NOA81, NOA83H, or NOA88, to mention a few examples.

The liquid bonding material 18 may also be applied to the surface of the mask 16, also in a liquid phase. The fluid properties of the adhesive 18 after a precure, enable adjustment (indicated by arrows in FIG. 3) of the pellicle frame 14 on the mask 16 without inducing stress to the mask 16 or the pellicle 12.

Once the pellicle 12 is in the desired position, a curable bonding material 18 may be converted to a solid phase by non-contact curing. In one embodiment, ultraviolet exposure may be utilized to cure the bonding material 18. In another embodiment, thermal curing may be utilized. As a result of curing, the adhesive 18 becomes a hard binding material between the pellicle 12 and the mask 16. The same procedure may be utilized to attach the hard pellicle 12 to the pellicle frame 14. In some embodiments, pellicles 12 can be fabricated to meet the flatness requirement and will also be able to maintain their shape and flatness after attachment to photomask 16.

Advantageously, the curable bonding material 18 has a sufficiently low viscosity to fill the gap between the mask 16 and the pellicle frame 14 or the pellicle 12 in the pellicle frame 14 to produce a hermetic seal without inducing stress. The volume of the adhesive 18 advantageously does not significantly change during the curing process to maintain the desired relative position and therefore the low stress properties of the seal after mounting the pellicle 12. The cured adhesive 18 can be chemically dissolved to allow removal of pellicle 12 or pellicle assembly 12 and 14 in some embodiments. Furthermore, to maintain mechanical stability during use of the masking of a photolithography exposure tool, the adhesive material 18 may be rigid enough to have sufficient adhesion to the mask 16 and the frame 14 (or the pellicle and pellicle frame). Finally, the cured adhesive may be chemically stable without outgassing under exposure to light and to the ambient environment during the operation of the lithography tool.

An adhesive 18 may be applied from a container through a nozzle or syringe that is sized to approximately match the size of the pellicle frame 14. Any bubbles in the container and the nozzle may be eliminated before adhesive application. This process can be automated with high volume manufacturing of masks.

In attaching the pellicle frame 14 to a mask 16, the pellicle frame 14 with the adhesive may be brought to rest on the mask 16. In attaching the pellicle 12 to the pellicle frame 14, the pellicle 12 can be placed on the frame 14 with the adhesive or vice versa. During the mounting to the mask or the pellicle plate, the pellicle frame 14 can be held on a stage that allows precise adjustment of the frame tool and translation to its desired location. This may prevent the adhesive 18 from being smeared during mounting. The pellicle frame 14 can also be placed on an adjustable stage before the adhesive is applied.

Since the masks on the pellicle plates are relatively flat, the interface with the pellicle frame leaves only very small gaps that can be easily filled with the low viscosity liquid phase adhesive 18.

After the pellicle frame 14 with the adhesive is brought into contact with the mask 16 or the pellicle 12, the adhesive 18 can be cured by directing high intensity visible or ultraviolet light on the seam area. Referring to FIG. 4, a suitable light for source L for this purpose may depend on the adhesive, but usually can be a mercury arc lamp or a fluorescent lamp.

The source L may be specifically designed to direct the light on all four edges of the pellicle 12 or to cure the adhesive 18 one frame edge 14 at a time. Since the hard pellicle 12 is made of fused silica, which is transparent to visible and ultraviolet light, the light can be directed at the adhesive seam from the outer side of the pellicle frame 14, from the inner side of the pellicle frame 14, through the pellicle 12, through the mask 16, or guided through the pellicle frame 14. As a result of curing, the adhesive 18 may form a strong bond between the mask 16 and the pellicle 14.

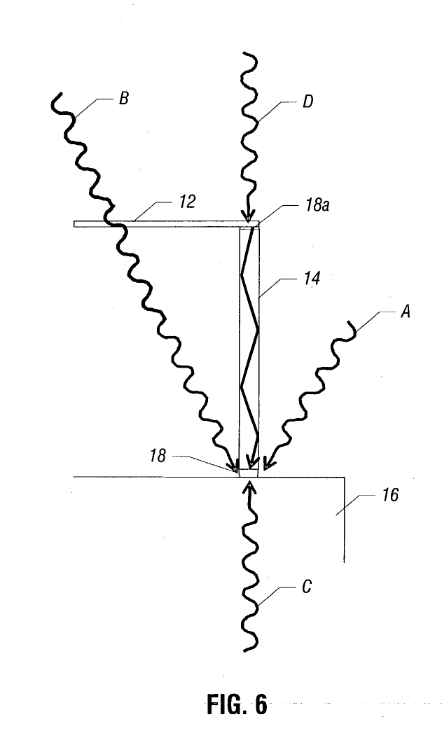

Referring to FIG. 6, it can be seen that the exposure of the adhesive 18 may be, as indicated at A, from the outer side of the pellicle frame 14. Alternatively, it may be from the inner side of the pellicle frame 14 through the pellicle 12 as indicated at B. Still another alternative, the exposure may be through the mask 16 as indicated at C. But still another alternative, the light may be guided to through the pellicle frame 14, as indicated at D, since the pellicle is made of fused silica that is transparent to visible and ultraviolet light. Upper adhesive 18a, which may be the same as the lower adhesive 18, may be applied between the pellicle 12 and frame 14.

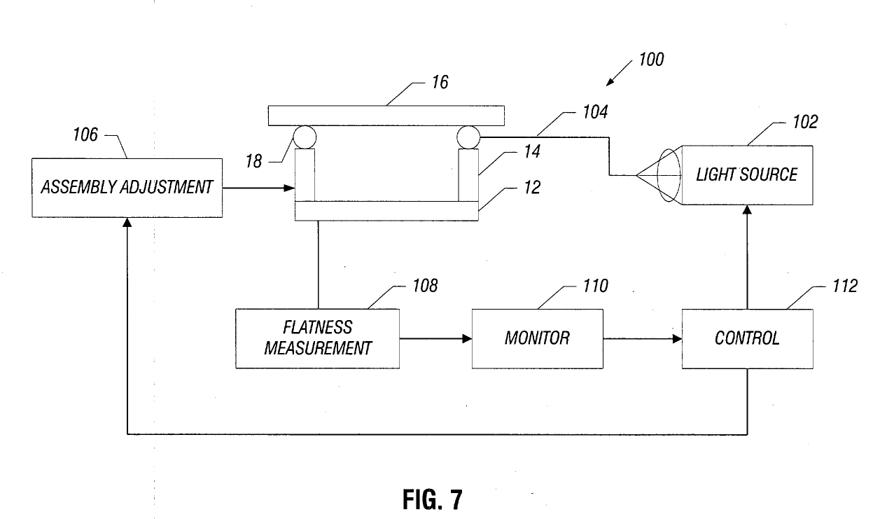

Referring to FIG. 7, a light delivery system 100 may include a light source 102 to generate a light beam that may be directed over an optical fiber 104 to the precise point where optical energy is needed, such as the location of the adhesive 18 as indicated by the paths A-D in FIG. 6. A surface flatness monitoring instrument 108 may be utilized to control the pellicle shape in real time and to freeze the pellicle in a desired shape in space by using the pellicle assembly adjustment 106 and by turning on the curing mechanism at the appropriate time. The flatness measurement device 108 may be coupled to a monitor 110 and a control 112 that provides feedback to control the light source 102. The control 112 also provides feedback to an assembly adjustment 106 that adjusts the portions of the assembled components. The entire system may be temperature controlled to produce a low stress bond between the mask 16 and the pellicle frame 14 (or pellicle 12 and pellicle frame 14) at a temperature that matches the temperature at which the mask-pellicle assembly is used in a wafer exposure tool. Thus, in some embodiments, light may be delivered via the optical fiber 104 and control system to a precise location at the precise time and temperature and with the precise functional intensity in some embodiments.

In accordance with some embodiments of the present invention, the adhesive 18 may be applied in the liquid phase and converted to a solid phase by curing. The liquid phase has low enough viscosity to fill the gap between the mask and the pellicle frame or between the pellicle and the pellicle frame to produce a seal without inducing stress in some cases. Advantageously, the volume of the adhesive does not significantly change during the curing process. After curing, the adhesive 18 may have a strong adhesion to the mask 16 and pellicle frame 14 or pellicle 12 and pellicle frame 14. The cured material may be rigid enough to have sufficient mechanical stability when the mask is used in a lithography exposure tool. Advantageously, the cured material may be chemically dissolved to allow pellicle removal. The cured material, advantageously, does not degrade upon exposure to light or ambient atmosphere during the operation of the tool. Also, the most advantageous cured materials do not outgas compounds that can redeposit on the mask 16. In some embodiments of the present invention, the techniques and materials described herein may be utilized to mount either a hard or a soft pellicle to a lithographic mask with reduced stress and reduced distortion of the pellicle and the mask.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
applying a liquid bonding material between a pair of photomask elements to be joined; and
curing the bonding material to secure the elements.

2. The method of claim 1 including applying a bonding material between a photomask and a pellicle frame.

3. The method of claim 1 including applying the bonding material between the pellicle and the pellicle frame.

4. The method of claim 1 including applying a light curable bonding material.

5. The method of claim 4 including applying an ultraviolet light curable bonding material.

6. The method of claim 4 including an optical fiber system to deliver the light directly to bonding material.

7. The method of claim 1 including precuring the bonding material, positioning the elements to be joined and thereafter curing the bonding material to secure the elements.

8. The method of claim 1 including using an optically clear bonding material.

9. The method of claim 1 including applying light to said bonding material through a pellicle.

10. The method of claim 1 including applying light to the bonding material between a pellicle frame and a photomask through said pellicle frame.

11. The method of claim 1 including a temperature-controlled flatness metrology instrument and positioning apparatus to monitor and control a pellicle to acquire a desired shape of the pellicle.

12. The method of claim 1 including applying light to cure said bonding material through a photomask.

13. A lithography apparatus comprising:
a pellicle frame;
a pellicle;
a photomask; and
a curable liquid adhesive between at least two of said pellicle, said pellicle frame, and said photomask.

14. The apparatus of claim 13 wherein said adhesive is between the photomask and the pellicle frame.

15. The apparatus of claim 13 wherein said adhesive is between the pellicle and the pellicle frame.

16. The apparatus of claim 13 wherein said adhesive is a light curable liquid bonding material.

17. The apparatus of claim 13 wherein said adhesive is an ultraviolet light curable bonding material.

18. The apparatus of claim 13 wherein said bonding material is optically clear.

19. The apparatus of claim 13 wherein said bonding material in the liquid phase has a viscosity of less than 500 centipoise.

20. The apparatus of claim 13 wherein said pellicle is a hard pellicle.

21. The apparatus of claim 13 wherein said adhesive converts from a liquid phase to a solid phase without significantly changing its volume.

22. A method comprising:
applying a liquid bonding material having a viscosity less than 500 centipoise between a pair of photomask elements to be joined;
positioning said elements relative to one another while in contact with said bonding material; and
curing the bonding material to secure the elements.

23. The method of claim 22 including applying a bonding material between a photomask and a pellicle frame.

24. The method of claim 23 including applying the bonding material between the pellicle and the pellicle frame.

25. The method of claim 23 including using an ultraviolet light curable bonding material.

26. The method of claim 23 including using light to cure said liquid bonding material to a solid phase.

27. The method of claim 26 including applying a light to the bonding material through a pellicle.

28. The method of claim 26 including applying light to the bonding material between a pellicle frame and a photomask through said pellicle frame.

29. The method of claim 26 including applying light to cure said bonding material through the photomask.
